(19) United States
(12) Patent Application Publication
(10) Pub. No.: US 2011/0286484 A1
(43) Pub. Date: Nov. 24, 2011

(54) System and Method of Multi-Wavelength Laser Apparatus

(75) Inventors: James W. Raring, Fremont, CA (US); Paul Rudy, Fremont, CA (US); Eric Hall, Fremont, CA (US)

(73) Assignee: Sorra, Inc., Fremont, CA (US)

(21) Appl. No.: 13/114,806

(22) Filed: May 24, 2011

Related U.S. Application Data
(60) Provisional application No. 61/347,800, filed on May 24, 2010.

(51) Int. Cl. H01S 5/30; H01S 5/343

(52) U.S. Cl. 372/44.011

(57) ABSTRACT

A system and method for providing laser diodes emitting multiple wavelengths is described. Multiple wavelengths and/or colors of laser output are obtained by having multiple laser devices, each emitting a different wavelength, packaged onto the same substrate. In other embodiments, multiple laser devices having different wavelengths are formed from the same substrate.

### CROSS REFERENCE TO RELATED APPLICATION

This application claims priority to U.S. Provisional Patent Application No. 61/347,800, filed 24 May 2010, which is incorporated by reference herein for all purposes.

### BACKGROUND OF THE INVENTION

The present invention is directed to system and method for providing laser diodes emitting multiple wavelengths. More specifically, multiple wavelengths and/or colors of laser output are obtained in various configurations. In certain embodiments, multiple laser beam outputs are obtained by having multiple laser devices, each emitting a different wavelength, packaged onto the same substrate. In other embodiments, multiple laser devices having different wavelengths are formed from the same substrate. Depending on the application, laser beams of different wavelengths are combined. There are other embodiments as well.

In the late 1800's, Thomas Edison invented the light bulb. The conventional light bulb, commonly called the “Edison bulb,” has been used for over one hundred years for a variety of applications including lighting and displays. The conventional light bulb uses a tungsten filament enclosed in a glass bulb sealed in a base, which is screwed into a socket. The socket is coupled to an AC power or DC power source. The conventional light bulb can be found commonly in houses, buildings, and outdoor lightings, and other areas requiring light or displays. Unfortunately, drawbacks exist with the conventional Edison light bulb, including wasting energy as heat, reliability, emissions spectrum, and directionality.

In 1960, the laser was first demonstrated by Theodore H. Maiman at Hughes Research Laboratories in Malibu. This laser utilized a solid-state flash lamp-pumped synthetic ruby crystal to produce red laser light at 694 nm. By 1964, blue and green laser output was demonstrated by William Bridges at Hughes Aircraft utilizing a gas laser design called an Argon ion laser. The Ar-ion laser utilized a noble gas as the active medium and produce laser light output in the UV, blue, and green wavelengths including 351 nm, 454.6 nm, 457.9 nm, 465.8 nm, 476.5 nm, 488.0 nm, 496.5 nm, 501.7 nm, 514.5 nm, and 528.7 nm. The Ar-ion laser had the benefit of producing highly directional and focusable light with a narrow spectral output, but the wall plug efficiency was <0.1%, and the size, weight, and cost of the lasers were undesirable as well.

As laser technology evolved, more efficient lamp pumped solid state laser designs were developed for the red and infrared wavelengths, but these technologies remained a challenge for blue and green and blue lasers. As a result, lamp pumped solid state lasers were developed in the infrared, and the output wavelength was converted to the visible using specialty crystals with nonlinear optical properties. A green lamp pumped solid state laser had 3 stages: electricity powers lamp, lamp excites gain crystal which lases at 1064 nm, 1064 nm goes into frequency conversion crystal which converts to visible 532 nm. The resulting green and blue lasers were called “lamped pumped solid state lasers with second harmonic generation” (LPSS with SHG) had wall plug efficiency of ˜1%, and were more efficient than Ar-ion gas lasers, but were still too inefficient, large, expensive, fragile for broad deployment outside of specialty scientific and medical applications. Additionally, the gain crystal used in the solid state lasers typically had energy storage properties which made the lasers difficult to modulate at high speeds which limited its broader deployment.

To improve the efficiency of these visible lasers, high power diode (or semiconductor) lasers were utilized. These “diode pumped solid state lasers with SHG” (DPSS with SHG) had 3 stages: electricity powers 808 nm diode laser, 808 nm excites gain crystal which lases at 1064 nm, 1064 nm goes into frequency conversion crystal which converts to visible 532 nm. The DPSS laser technology extended the life and improved the wall plug efficiency of the LPSS lasers to 5-10%, and further commercialization ensue into more high end specialty industrial, medical, and scientific applications. However, the change to diode pumping increased the system cost and required precise temperature controls, leaving the laser with substantial size, power consumption while not addressing the energy storage properties which made the lasers difficult to modulate at high speeds.

Various types of lasers as described above have many applications. Typically, one or more laser devices of the same wavelength or color are provided as a single package. For example, conventional systems typically include multiple packaged laser devices, and these packaged devices are combined to have multiple colors. As a result, it is often difficult to reduce the size of combined laser devices, and it often incurs extra costs for combining laser devices.

### BRIEF SUMMARY OF THE INVENTION

The present invention is directed to system and method for providing laser diodes emitting multiple wavelengths. More specifically, multiple wavelengths and/or colors of laser output are obtained in various configurations. In certain embodiments, multiple laser beam outputs are obtained by having multiple laser devices, each emitting a different wavelength, packaged onto the same substrate. In other embodiments, multiple laser devices having different wavelengths are formed from the same substrate. Depending on the application, laser beams of different wavelengths may be combined.

According to one embodiment, the present invention provides an optical device includes a gallium and nitrogen containing substrate including a first crystalline surface region orientation. The device also includes an active region comprising a barrier layer and a light emission layer, the light emission layer being characterized by a graduated profile associated with a peak emission wavelength gradient, the peak emission wavelength gradient having a deviation of at least 10 nm. The device further includes a first cavity member overlaying a first portion of the emission layer, the first portion of the emission layer being associated with a first wavelength, the first cavity member being characterized by a length of at least 100 um and a width of at least 0.5 um, the first cavity member being adapted to emit a first laser beam at the first wavelength. The device additionally includes a second cavity member overlaying a second portion of the emission layer, the second portion of the emission layer being associated with a second wavelength, a difference between the first and second wavelengths being at least 50 nm, the second cavity member being characterized by a length of at least 100 um and a width of at least 0.5 um, the second cavity member being adapted to emit a second laser beam at a second wavelength. The device also includes an output region wherein the first laser beam and the second laser beam are combined.

In another embodiment, the devices includes an active region comprising a barrier layer and a plurality of light emission layers of differing wavelengths. The device additionally includes an output region wherein the first laser beam and the second laser beam are combined.

According to yet another embodiment, the present invention provides a method for forming an optical device. The method includes providing a gallium and nitrogen containing substrate including a first crystalline surface region orientation. The method also includes defining a first active region by performing a selective etching process. The method includes forming a barrier layer within the first active region, growing a first and second emission layers and forming cavity members over the layers.

According to yet another embodiment, the present invention provides an optical device having multiple active regions. The device includes a back member having a first surface. The device also includes a first substrate mounted on the first surface of the back member, the first substrate comprising a gallium and nitrogen material, the first substrate having a first crystalline surface region orientation. The device also includes a first active region comprising a first barrier layer and a first light emission layer, the first light emission layer being associated with a first wavelength. The device additionally includes a second substrate mounted on the first surface of the back member, the first substrate having a second crystalline surface region orientation. The device also includes a second active region comprising a second barrier layer and a second light emission layer, the second light emission layer being associated with a second wavelength, a difference between the first and second wavelengths being at least 10 nm. The device also includes a first cavity member overlaying the first light emission layer, the first cavity member being characterized by a length of at least 100 um and a width of at least 0.5 um, the first cavity member having a first surface, the first cavity member being adapted to emit a first laser beam at the first wavelength. The device also includes a second cavity member overlaying a second light emission layer, the second cavity member being characterized by a length of at least 100 um and a width of at least 0.5 um, the second cavity member having a second surface, the first and second surfaces being substantially parallel, the second cavity member being adapted to emit a second laser beam at a second wavelength. The device also includes an output region wherein the first laser beam and the second laser beam are combined.

The invention enables a cost-effective optical device for laser applications. In a specific embodiment, the optical device can be manufactured in a relatively simple and cost effective manner. Depending upon the embodiment, the present apparatus and method can be manufactured using conventional materials and/or methods according to one of ordinary skill in the art.

### BRIEF DESCRIPTION OF THE DRAWINGS

FIG. 1 is diagram illustrating a side-by-side emitter configuration;

FIG. 1A is a perspective view of a laser device fabricated on an off-cut m-plane {20-21} substrate;

FIG. 2A is a cross-sectional view of a laser device 200 fabricated on a {20-21}substrate;

FIG. 2B is a diagram illustrating a cross-section of an active region with graded emission wavelength;

FIG. 2C is a diagram illustrating a laser device with multiple active regions;

FIG. 3 is a diagram of copackaged green and blue laser diode mounted on common surface within a single package;

FIG. 4 is a diagram of copackaged red, green, and blue laser diodes mounted on common surface within a single package;

FIG. 5 is a simplified diagram illustrating two laser diodes sharing a submount;

FIG. 6 is a diagram illustrating a co-packaged red, green, and blue laser device; and

FIGS. 7-9 are diagrams illustrating laser diodes sharing mounting structures.

### DETAILED DESCRIPTION OF THE INVENTION

The present invention is directed to system and method for providing laser diodes emitting multiple wavelengths. More specifically, multiple wavelengths and/or colors of laser output are obtained in various configurations. In certain embodiments, multiple laser beam outputs are obtained by having multiple laser devices, each emitting a different wavelength, packaged onto the same substrate. In other embodiments, multiple laser devices having different wavelengths are formed from the same substrate. Depending on the application, laser beams of different wavelengths may be combined.

According to one embodiment, a way to create combine laser devices with multiple wavelengths is to form having an active region with multiple portions of light emitting layer, each portion being associated with a specific wavelength of color. According to another embodiment, multiple active layers, each associated with a specific wavelength or color, are provided to achieve multiple-wavelength outputs. For example, two or more laser cavities are provided in a side-by-side configuration such that the individual output spectrums could be convolved and captured into a single beam. Each of the laser cavities is situated on top a specific active region for emitting the wavelength associated with the active region. For example, adjacent laser diodes can utilize conventional in-plane laser geometries with cavity lengths ranging from 100 um to 3000 um and cavity widths ranging from 0.5 um to 50 um. It is to be appreciated that, in certain embodiments, conventional semiconductor laser fabrication techniques and equipment can be used to manufacturing optical devices and waveguide structures.

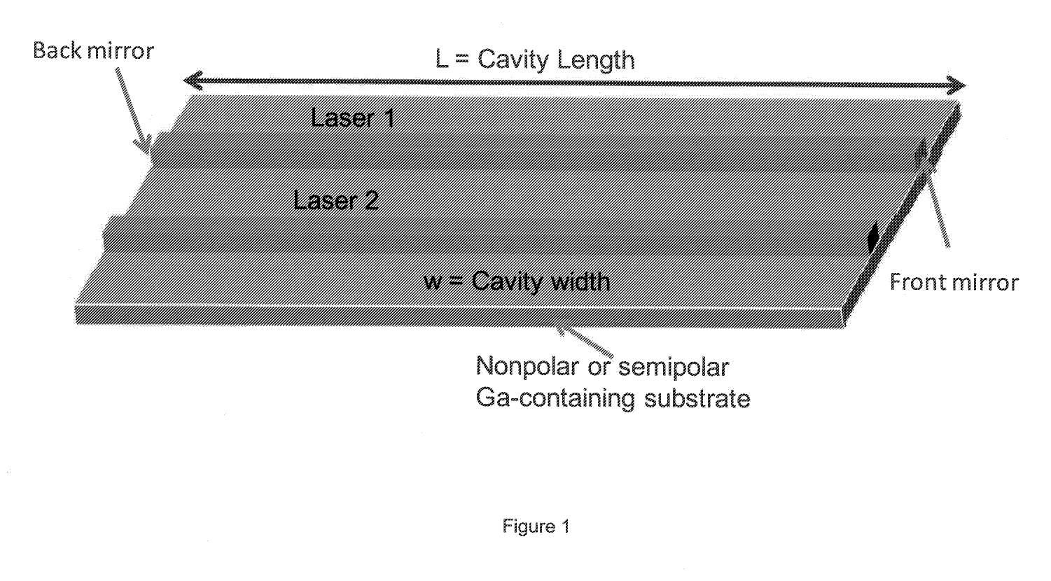

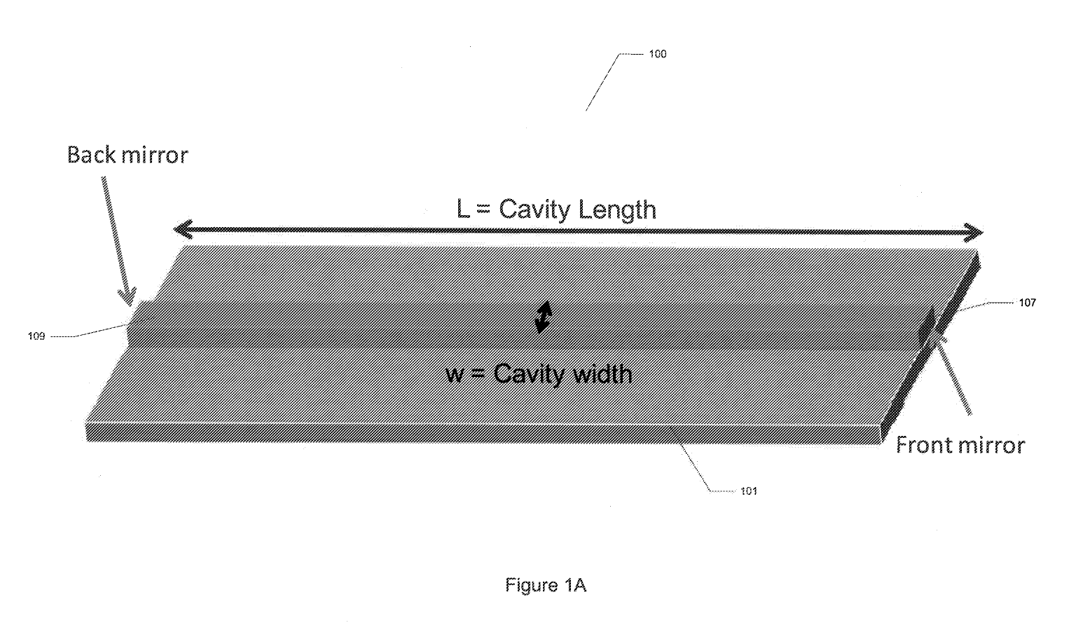

In a specific embodiment, side-by-side lasers are separated from one another at distances of about lum to 500 um. Depending on the application, these lasers can share a common set of electrodes or use separate electrodes. FIG. 1 is simplified schematic diagram illustrating a side-by-side emitter configuration according to an embodiment of the present invention. As shown in FIG. 1, laser 1 and laser 2 having separate cavity members are configured side by side. Depending on the application, the substrate for laser 1 and laser 2 can be nonpolar or semi-polar gallium-containing substrate. Both laser 1 and laser 2 have a front and back mirror. In a specific embodiment, laser 1 and laser 2 share a common cleaved surface. Depending on the application, dimension and configuration for laser 1 and laser 2 can be varied. Laser 1 and laser 2 are associated with different wavelengths and/or colors. For example, laser 1 is configured to emit green color laser beam and laser 2 is configured to emit blue color laser beam.

As an example, FIG. 1 provides an example of monolithically integrated green and blue laser diodes on a nonpolar or semipolar Ga-containing substrate, where laser 1 could generate an output wavelength of blue (425-470 nm) or green (510-545 nm) and laser 2 could generate an output wavelength of blue or green. While FIG. 1 only shows 2 lasers, there could be a multitude of lasers on the single-chip. The different wavelength lasers could be defined in several ways such as selective area growth, regrowth steps, quantum well intermixing, or single growth and etch step methods.

It is to be appreciated that in various embodiments, laser 1 and laser 2 are fabricated on a same semiconductor chip. Depending on the needs, laser 1 and laser 2 may have many permutations of wavelength and number of laser diodes fabricated on the same chip, where the wavelength ranges can be from 390-420 nm, 420-460 nm, 460-500 nm, 500-540 nm, and greater than 540 nm. Additionally, these lasers can share common cleaved facet mirrors edges. In a preferred embodiment, the laser devices are implemented using the {20-21} (semipolar) family of planes including {20-2-1}, or a plane within +/−8 deg of this plane, such as {30-31} or {30-3-1}. Different types of laser devices can be packaged together. For example, laser devices may be implemented using polar or c-plane (0001), nonpolar or m-plane/a-plane (10-10), (11-20), and/or semipolar {11-22}, {10-1-1}, {20-21}, {30-31}.

For many applications, the goal of having laser diodes of different colors is to combine laser beams in different colors. For example, laser beams emitted from laser 1 and laser 2 of FIG. 1 can be combined in various ways. In embodiment, free space optics are used to match the beam size and divergence and overlap beams in space. More specifically, the embodiment includes optics with dichroic coatings to pass one or more colors and reflect one or more colors. For example, polarization combination can also be used to combine lasers of the same color and increase power.

In certain embodiments, combining of laser beams can be achieved by using a set of waveguides (and/or cavity members) to match the beam size and divergence and overlap beams in space. For example, one input port is provided per laser with a single output port. Beam exits output port to then reach the device which forms the image (e.g., scanning mirror, LCOS, DLP, etc.). Waveguide entrance and exit ports may have optical properties to collimate the beam, rotate its polarization, etc.

As an example, a laser according to the present invention can be manufactured on m-plane. FIG. 1A is a simplified perspective view of a laser device fabricated on an off-cut m-plane {20-21} substrate according to an embodiment of the present invention. As shown, the optical device includes a gallium nitride substrate member 101 having the off-cut m-plane crystalline surface region. In a specific embodiment, the gallium nitride substrate member is a bulk GaN substrate characterized by having a semipolar or non-polar crystalline surface region. In a specific embodiment, the bulk nitride GaN substrate comprises nitrogen and has a surface dislocation density below 10⁵ cm⁻² to about 10⁸ cm⁻². The nitride crystal or wafer may comprise AlₓIn_{y}Ga_{1-x-y}N, where 0≦x, y, x+y≦1. In one specific embodiment, the nitride crystal comprises GaN. In one or more embodiments, the GaN substrate has threading dislocations, at a concentration between about 10⁵ cm⁻² and about 10⁸ cm⁻², in a direction that is substantially orthogonal or oblique with respect to the surface. As a consequence of the orthogonal or oblique orientation of the dislocations, the surface dislocation density is below about 10⁵ cm⁻² to about 10⁸ cm⁻². In a specific embodiment, the device can be fabricated on a slightly off-cut semipolar substrate as described in U.S. Provisional No. 61/164,409 filed Mar. 28, 2009, commonly assigned, and hereby incorporated by reference herein.

In a specific embodiment on the {20-21} family of GaN crystal planes, the device has a laser stripe region formed overlying a portion of the off-cut crystalline orientation surface region. In a specific embodiment, the laser stripe region is characterized by a cavity orientation substantially in a projection of a c-direction, which is substantially normal to an a-direction. In a specific embodiment, the laser strip region has a first end 107 and a second end 109. In a preferred embodiment, the device is formed on a projection of a c-direction on a {20-21} gallium and nitrogen containing substrate having a pair of cleaved mirror structures, which face each other.

In a preferred embodiment, the device has a first cleaved facet provided on the first end of the laser stripe region and a second cleaved facet provided on the second end of the laser stripe region. In one or more embodiments, the first cleaved is substantially parallel with the second cleaved facet. Mirror surfaces are formed on each of the cleaved surfaces. The first cleaved facet comprises a first mirror surface. In a preferred embodiment, the first mirror surface is provided by a top-side skip-scribe scribing and breaking process. The scribing process can use any suitable techniques, such as a diamond scribe or laser scribe or combinations. In a specific embodiment, the first mirror surface comprises a reflective coating. The reflective coating is selected from silicon dioxide, hafnia, and titania, tantalum pentoxide, zirconia, including combinations, and the like. Depending upon the embodiment, the first mirror surface can also comprise an anti-reflective coating.

Also in a preferred embodiment, the second cleaved facet comprises a second mirror surface. The second mirror surface is provided by a top side skip-scribe scribing and breaking process according to a specific embodiment. Preferably, the scribing is diamond scribed or laser scribed or the like. In a specific embodiment, the second mirror surface comprises a reflective coating, such as silicon dioxide, hathia, and titania, tantalum pentoxide, zirconia, combinations, and the like. In a specific embodiment, the second mirror surface comprises an anti-reflective coating.

In a specific embodiment, the laser stripe has a length and width. The length ranges from about 50 microns to about 3000 microns. The strip also has a width ranging from about 0.5 microns to about 50 microns, but can be other dimensions. In a specific embodiment, the width is substantially constant in dimension, although there may be slight variations. The width and length are often formed using a masking and etching process, which are commonly used in the art.

In a specific embodiment, the present invention provides an alternative device structure capable of emitting 501 nm and greater light in a ridge laser embodiment. The device is provided with one or more of the following epitaxially grown elements:

an n-GaN cladding layer with a thickness from 100 nm to 3000 nm with Si doping level of 5E17 to 3El8 cm-3

an n-side SCH layer comprised of InGaN with molar fraction of indium of between 3% and 10% and thickness from 20 to 100 nm

multiple quantum well active region layers comprised of at least two 2.0-5.5 nm InGaN quantum wells separated by thin 2.5 nm and greater, and optionally up to about 8 nm, GaN barriers

a p-side SCH layer comprised of InGaN with molar a fraction of indium of between 1% and 10% and a thickness from 15 nm to 100 nm

an electron blocking layer comprised of AlGaN with molar fraction of aluminum of between 12% and 22% and thickness from 5 nm to 20 nm and doped with Mg.

a p-GaN cladding layer with a thickness from 400 nm to 1000 nm with Mg doping level of 2E17 cm-3 to 2El9 cm-3

a p++-GaN contact layer with a thickness from 20 nm to 40 nm with Mg doping level of 1E19 cm-3 to 1E21 cm-3

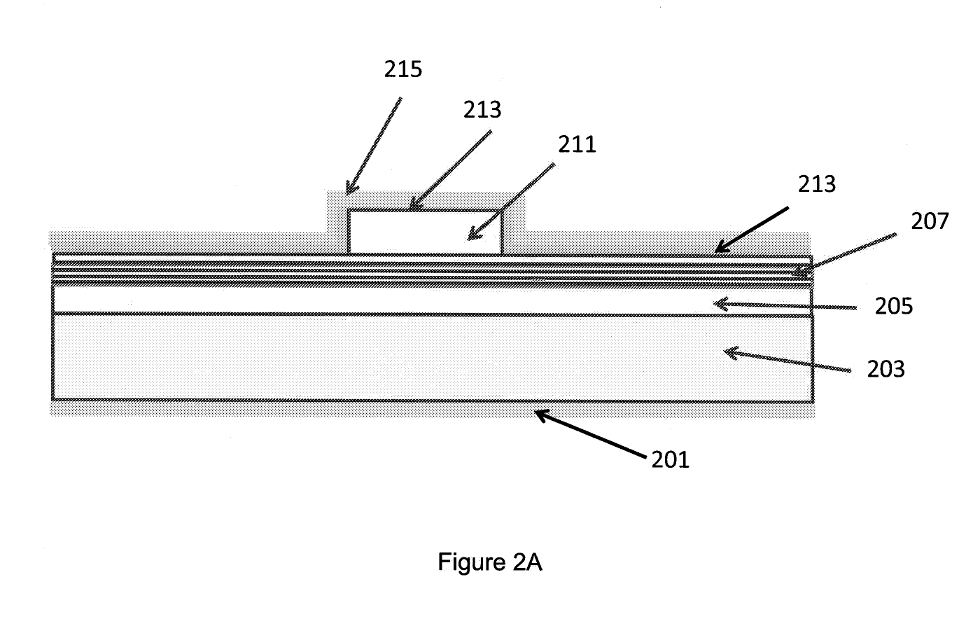

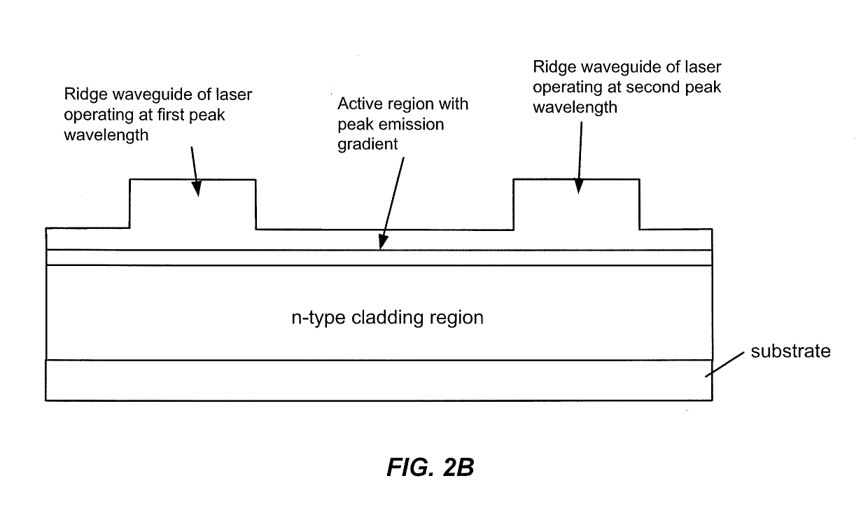

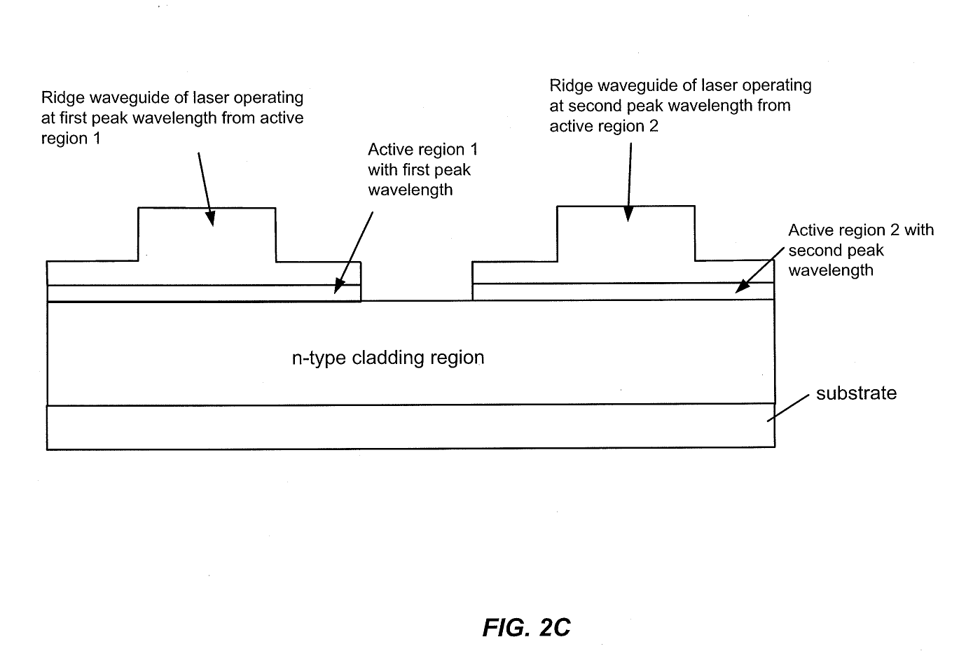

FIG. 2A is a cross-sectional view of a laser device 200 fabricated on a {20-21} substrate according to an embodiment of the present invention. As shown, the laser device includes gallium nitride substrate 203, which has an underlying n-type metal back contact region 201. In a specific embodiment, the metal back contact region is made of a suitable material such as those noted below and others.

In a specific embodiment, the device also has an overlying n-type gallium nitride layer 205, an active region 207, and an overlying p-type gallium nitride layer structured as a laser stripe region 209. In a specific embodiment, each of these regions is formed using at least an epitaxial deposition technique of metal organic chemical vapor deposition (MOCVD), molecular beam epitaxy (MBE), or other epitaxial growth techniques suitable for GaN growth. In a specific embodiment, the epitaxial layer is a high quality epitaxial layer overlying the n-type gallium nitride layer. In some embodiments the high quality layer is doped, for example, with Si or O to form n-type material, with a dopant concentration between about 10¹⁶ cm⁻³ and 10²⁰ cm⁻³.

In a specific embodiment, an n-type AlᵤInᵥGa₁₋ᵤ₋ᵥN layer, where 0≦u, v, u+v≦1, is deposited on the substrate. In a specific embodiment, the carrier concentration may lie in the range between about 10¹⁶ cm⁻³ and 10²⁰ cm⁻³. The deposition may be performed using metalorganic chemical vapor deposition (MOCVD) or molecular beam epitaxy (MBE). Of course, there can be other variations, modifications, and alternatives.

As an example, the bulk GaN substrate is placed on a susceptor in an MOCVD reactor. After closing, evacuating, and back-filling the reactor (or using a load lock configuration) to atmospheric pressure, the susceptor is heated to a temperature between about 1000 and about 1200 degrees Celsius in the presence of a nitrogen-containing gas. In one specific embodiment, the susceptor is heated to approximately 1100 degrees Celsius under flowing ammonia. A flow of a gallium-containing metalorganic precursor, such as trimethylgallium (TMG) or triethylgallium (TEG) is initiated, in a carrier gas, at a total rate between approximately 1 and 50 standard cubic centimeters per minute (sccm). The carrier gas may comprise hydrogen, helium, nitrogen, or argon. The ratio of the flow rate of the group V precursor (ammonia) to that of the group III precursor (trimethylgallium, triethylgallium, trimethylindium, trimethylaluminum) during growth is between about 2000 and about 12000. A flow of disilane in a carrier gas, with a total flow rate of between about 0.1 and 10 sccm, is initiated.

In a specific embodiment, the laser stripe region is made of the p-type gallium nitride layer 209. In a specific embodiment, the laser stripe is provided by an etching process selected from dry etching or wet etching. In a preferred embodiment, the etching process is dry. As an example, the dry etching process is an inductively coupled process using chlorine bearing species or a reactive ion etching process using similar chemistries. Again as an example, the chlorine bearing species are commonly derived from chlorine gas or the like. The device also has an overlying dielectric region, which exposes 213 contact region. In a specific embodiment, the dielectric region is an oxide such as silicon dioxide or silicon nitride. The contact region is coupled to an overlying metal layer 215. The overlying metal layer is a multilayered structure containing gold and platinum (Pt/Au), nickel gold (Ni/Au).

In a specific embodiment, the laser device has active region 207. The active region can include one to twenty quantum well regions according to one or more embodiments. As an example following deposition of the n-type AlᵤInᵥGa₁₋ᵤ₋ᵥN layer for a predetermined period of time, so as to achieve a predetermined thickness, an active layer is deposited. The active layer may be comprised of multiple quantum wells, with 2-10 quantum wells. The quantum wells may be comprised of InGaN with GaN barrier layers separating them. In other embodiments, the well layers and barrier layers comprise Al_{w}InₓGa_{1-w-x}N and Al_{y}In_{z}Ga_{i-y-z}N, respectively, where 0≦w, x, y, z, w+x, y+z≦1, where w<u, y and/or x>v, z so that the bandgap of the well layer(s) is less than that of the barrier layer(s) and the n-type layer. The well layers and barrier layers may each have a thickness between about 1 nm and about 20 nm. The composition and structure of the active layer are chosen to provide light emission at a preselected wavelength. The active layer may be left undoped (or unintentionally doped) or may be doped n-type or p-type.

In a specific embodiment, the active region can also include an electron blocking region, and a separate confinement heterostructure. In some embodiments, an electron blocking layer is preferably deposited. The electron-blocking layer may comprise AlₛInₜGa₁₋ₛ₋ₜN, where 0≦s, t, s+t≦1, with a higher bandgap than the active layer, and may be doped p-type. In one specific embodiment, the electron blocking layer comprises AlGaN. In another embodiment, the electron blocking layer comprises an AlGaN/GaN super-lattice structure, comprising alternating layers of AlGaN and GaN, each with a thickness between about 0.2 nm and about 5 nm.

As noted, the p-type gallium nitride structure is deposited above the electron blocking layer and active layer(s). The p-type layer may be doped with Mg, to a level between about 10¹⁶ cm⁻³ and 10²² cm⁻³, and may have a thickness between about 5 nm and about 1000 nm. The outermost 1-50 nm of the p-type layer may be doped more heavily than the rest of the layer, so as to enable an improved electrical contact. In a specific embodiment, the laser stripe is provided by an etching process selected from dry etching or wet etching. In a preferred embodiment, the etching process is dry. The device also has an overlying dielectric region, which exposes 213 contact region. In a specific embodiment, the dielectric region is an oxide such as silicon dioxide.

According to an embodiment, the as-grown material gain peak is varied spatially across a wafer. As a result, different wavelength and/or color can be obtained from one fabricated laser to the next laser on the same wafer. The as-grown gain peak wavelength can be shifted using various method according to embodiments of the present invention. According to one embodiment, the present invention utilizes growth non-uniformities where the as-grown material has an emission wavelength gradient. For example, the growth non-uniformity can be obtained a result of temperature and/or growth rate gradients in the light emitting layers in the epitaxial growth chamber. For example, such wavelength gradients can be intentional or non-intentional, and the differences in wavelengths range from 10 to 40 nm deviation. For example, this method enables multiple lasers on the same chip to operate at different wavelengths.

In a specific embodiment, an optical device configured to provide laser beams at different wavelengths is provided. The device includes a gallium and nitrogen containing substrate including a first crystalline surface region orientation. For example, the substrate member may have a surface region on the polar plane (c-plane), nonpolar plane (m-plane, a-plane), and semipolar plain ({11-22}, {10-1-1}, {20-21}, {30-31}, {20-2-1}, {30-3-1}). The device also includes an active region comprising a barrier layer and a light emission layer, the light emission layer being characterized by a graduated profile associated with a peak emission wavelength gradient, the peak emission wavelength gradient having a deviation of at least 10 nm. Also, the device includes a first cavity member overlaying a first portion of the emission layer, the first portion of the emission layer being associated with a first wavelength, the first cavity member being characterized by a length of at least 100 um and a width of at least 0.5 um, the first cavity member being adapted to emit a first laser beam at the first wavelength. The device further includes a second cavity member overlaying a second portion of the emission layer, the second portion of the emission layer being associated with a second wavelength, a difference between the first and second wavelengths being at least 50 nm, the second cavity member being characterized by a length of at least 100 um and a width of at least 0.5 um, the second cavity member being adapted to emit a second laser beam at a second wavelength. Additionally, the device includes an output region wherein the first laser beam and the second laser beam are combined.

To combine the first and second laser beams, various means may be used. In one embodiment, a plurality of optics having dichroic coatings is used for combining the first and the second laser beams. In another embodiment, a plurality of polarizing optics are used for combining the first and the second laser beams. Depending on the application, the first wavelength can be associated with the green color or the blue color. For example, the first and second wavelengths are associated with different colors.

In a specific embodiment, the first cavity member and the second cavity member share a common cleaved facet of mirror edges. For example, the common cleaved facet is specifically configured to allow combination of the first and second laser beams. In various embodiments, the devices may further comprise a surface ridge architecture and/or a buried hetereostructure architecture. In one embodiment, the active region includes a first and second gallium and nitrogen containing cladding layers and an indium and gallium containing emitting layer positioned between the first and second cladding layers.

For operating the device, a plurality of metal electrodes can be used for selectively exciting the active region. For example, the active may include two or more quantum well regions, three or more quantum well regions, and even six or more quantum well regions. FIG. 2B is a simplified diagram illustrating a cross-section of an active region with graded emission wavelength.

In certain embodiments of the present invention, multiple laser wavelengths output is obtained by manipulating the as-grown gain peak through selective area epitaxy (SAE), where dielectric patterns are used to define the growth area and modify the composition of the light emitting layers. Among other things, such modification of the composition can be used to cause different gain peak wavelengths and hence different lasing wavelengths. For example, by using SAE processes, a device designer can have a high degree of spatial control and can safely achieve 10-30 nm, and sometimes even more, of wavelength variation over the lasers. For example, the SAE process is described in a U.S. patent application Ser. No. 12/484,924, filed Jun. 15, 2009, entitled “SELECTIVE AREA EPITAXY GROWTH METHOD AND STRUCTURE FOR MULTI-COLOR DEVICES”. For example, this method enables multiple lasers on the same chip to operate at different wavelengths.

According to an embodiment, the following steps, using SAE techniques, are performed in a method for forming a device that includes laser devices capable of providing multiple wavelengths and/or colors:
1. providing a gallium and nitrogen containing substrate including a first crystalline surface region orientation;
2. defining an active region;
3. forming a barrier layer within the active region;
4. growing a plurality of light emission layers within the active region using a selective area epitaxy process, the plurality of light emission layers including a first emission layer and a second emission layer, the first emission layer being characterized by a first gain peak wavelength, the second emission layer being characterized by a second gain peak wavelength, a difference between the first gain peak wavelength and the second gain peak wave length being at least 10 nm;
5. forming a first cavity member overlaying the first emission layer, the first cavity member being characterized by a length of at least 100 um and a width of at least 0.5 um, the first cavity member being adapted to emit a first laser beam at the first wavelength;
6. forming a second cavity member overlaying the second the emission layer, the second cavity member being characterized by a length of at least 100 um and a width of at least 0.5 um, the second cavity member being adapted to emit a second laser beam at the second wavelength;
7. providing an output region wherein the first laser beam and the second laser beam are combined

It is to be appreciated that the method described above can be implemented using various types of substrate. As explained above, the substrate member may have a surface region on the polar plane (c-plane), nonpolar plane (m-plane, a-plane), and semipolar plain ({11-22}, {10-1-1}, {20-21}, {30-31}, {20-2-1}, {30-3-1}). For example, during the growth phase of the light emission layer, growth areas are defined by dielectric layers. In a specific embodiment, the emission layers at each of the growth area have different spatial dimensions (e.g., width, thickness) and/or compositions (e.g., varying concentrations for indium, gallium, and nitrogen). In a preferred embodiment, the growth areas a configured with one or more special structures that include from annular, trapezoidal, square, circular, polygon shaped, amorphous shaped, irregular shaped, triangular shaped, or any combinations of these. For example, each of the emission layers is associated with a specific wavelength and/or color. As explained above, differences in wavelength among the emission layers may can range from 1 nm to 40 nm.

In a specific embodiment, a laser apparatus manufactured using SAE process with multiple wavelengths and/or color is provided. The laser apparatus includes a gallium and nitrogen containing substrate including a first crystalline surface region orientation. The apparatus also includes an active region comprising a barrier layer and a plurality of light emission layers, the plurality of light emission layers including a first emission layer and a second emission layer, the first emission layer being characterized by a first wavelength, the second emission layer being characterized by a second wavelength, a difference between the first wavelength and the second wavelength is at least 10 nm. For example, the first and second emission layers are formed using selective area epitaxy processes.

The apparatus includes a first cavity member overlaying the first emission layer, the first cavity member being characterized by a length of at least 100 um and a width of at least 0.5 um, the first cavity member being adapted to emit a first laser beam at the first wavelength. The apparatus also includes a second cavity member overlaying the second the emission layer, the second cavity member being characterized by a length of at least 100 um and a width of at least 0.5 um the second cavity member being adapted to emit a second laser beam at the second wavelength. The apparatus additionally includes an output region wherein the first laser beam and the second laser beam are combined.

As explained above, it is often desirable to combine the first and second wavelengths or colors associated thereof for various applications. For example, the apparatus may have optics having dichroic coatings for combining the first and the second laser beam. In one embodiment, the apparatus includes a plurality of polarizing optics for combining the first and the second laser beam. In a specific embodiment, the first cavity member and the second cavity member share a common cleaved facet of mirror edges, which is configured to combine the first and second laser beams.

The first and second laser beams can be associated with a number of color combinations. For example, the first wavelength is associated with a green color and the second wavelength is associated with a blue color. It is to be appreciated that the laser apparatus can be implemented on various types of substrates. For example, the first crystalline surface region orientation can be a {20-21} plane, and first crystalline surface region orientation can also be a {30-31} plane.

The laser apparatus may also include other structures, such as a surface ridge architecture, a buried hetereostructure architecture, and/or a plurality of metal electrodes for selectively exciting the active region For example, the active region comprises a first and second gallium and nitrogen containing cladding layers and an indium and gallium containing emitting layer positioned between the first and second cladding layers. The laser apparatus may further includes an n-type gallium and nitrogen containing material and an n-type cladding material overlying the n-type gallium and nitrogen containing material.

In certain embodiments of the present invention, multiple laser wavelengths and/or colors are obtained by providing multiple active regions, and each of the active regions is associated with a specific wavelength (or color). More specifically, multiple growth of active regions is performed across a single chip. In this technique a wafer is loaded in a growth chamber for the growth of an active region with one gain peak. After this growth, the wafer is subjected to one or more lithography and processing steps to remove a portion of the active region in some areas of the wafer. The wafer would then be subjected to a second growth where a second active region with a second peak gain wavelength is grown. Depending on the specific need, the processes of growing and removing active regions can be repeated many times. Eventually, be followed by the fabrication of laser diodes strategically positioned relative to these different active regions to enable lasing at various wavelengths.

FIG. 2C is a diagram illustrating a laser device with multiple active regions according embodiments of the present invention.

According to an embodiment, the following steps are performed in a method for forming a device that includes laser devices having multiple active regions:
1. providing a gallium and nitrogen containing substrate including a first crystalline surface region orientation;
2. defining a first active region by performing a selective etching process;
3. forming a barrier layer within the first active region;
4. growing a first emission layer within the first active region, the first emission layer being characterized by a first wavelength;
5. defining a second active region by performing a selective etching process;
6. growing a second emission layer within the second active area, the second emission layer being characterized by a second wavelength, a difference between the first gain peak wavelength and the second gain peak wave length being at least 10 nm;
7. forming a first cavity member overlaying the first emission layer, the first cavity member being characterized by a length of at least 100 um and a width of at least 0.5 um, the first cavity member being adapted to emit a first laser beam at the first wavelength;
8. forming a second cavity member overlaying the second the emission layer, the second cavity member being characterized by a length of at least 100 um and a width of at least 0.5 um the second cavity member being adapted to emit a second laser beam at the second wavelength; and
9. aligning the first and second cavity members to combine the first and second laser beams at a predetermine region

Depending on the application, the above method may also includes other steps. For example, the method may include providing an optical member for combining the first and second laser beams. In one embodiment, the method includes shaping a first cleaved surface of the first cavity member, shaping a second cleaved surface of the second cavity member, and aligning the first and second cleaved surfaces to cause the first and second laser beams to combine.

It is to be appreciated that the method described above can be implemented using various types of substrate. As explained above, the substrate member may have a surface region on the polar plane (c-plane), nonpolar plane (m-plane, a-plane), and semipolar plain ({11-22}, {10-1-1}, {20-21}, {30-31}, {20-2-1}, {30-3-1}). In the method described above, two active regions and two cavity members are formed. For example, each active region and cavity member pair is associated with a specific wavelength. Depending on the application, additional active regions and cavity members may be formed to obtain desired wavelengths and/or spectral width. In a preferred embodiment, each of the active regions is characterized by a specific spatial dimension associated with a specific wavelength.

In a specific embodiment, a laser apparatus having multiple active regions that provide multiple wavelengths and/or colors is described. The laser apparatus includes a gallium and nitrogen containing substrate including a first crystalline surface region orientation. In a specific embodiment, the substrate comprises Indium bearing material. The apparatus also includes a first active region comprising a barrier layer and a first emission layer, the first emission layer being characterized by a first gain peak wavelength. The apparatus includes a second active region comprising a second emission layer, the second emission layer being characterized by a second gain peak wavelength, a difference between the first gain peak wavelength and the second gain peak wave length is at least 10 nm.

The apparatus further includes a first cavity member overlaying the first emission layer, the first cavity member being characterized by a length of at least 100 um and a width of at least 0.5 um, the first cavity member being adapted to emit a first laser beam at the first wavelength. The apparatus additionally includes a second cavity member overlaying the second the emission layer, the second cavity member being characterized by a length of at least 100 um and a width of at least 0.5 um the second cavity member being adapted to emit a second laser beam at the second wavelength. The apparatus further includes an output region wherein the first laser beam and the second laser beam are combined.

As explained above, it is often desirable to combine the first and second wavelengths or colors associated thereof for various applications. For example, the apparatus may have optics having dichroic coatings for combining the first and the second laser beam. In one embodiment, the apparatus includes a plurality of polarizing optics for combining the first and the second laser beam. In a specific embodiment, the first cavity member and the second cavity member share a common cleaved facet of mirror edges, which is configured to combine the first and second laser beams.

The first and second laser beams can be associated with a number of color combinations. For example, the first wavelength is associated with a green color and the second wavelength is associated with a blue color.

It is to be appreciated that the laser apparatus can be implemented on various types of substrates. For example, the first crystalline surface region orientation can be a {20-21} or {20-2-1} plane, and first crystalline surface region orientation can also be a {30-31} or {30-3-1} plane.

The laser apparatus may also include other structures, such as a surface ridge architecture, a buried hetereostructure architecture, and/or a plurality of metal electrodes for selectively exciting the active region For example, the active region comprises a first and second gallium and nitrogen containing cladding layers and an indium and gallium containing emitting layer positioned between the first and second cladding layers. The laser apparatus may further includes an n-type gallium and nitrogen containing material and an n-type cladding material overlying the n-type gallium and nitrogen containing material.

It is to be appreciated embodiments of the present invention provides method for obtaining multiple laser wavelengths and/or colors after the active regions have already been formed. More specifically, the gain-peak of the semiconductor material can be spatially manipulated post-growth through quantum well intermixing (QWI) processes and/or disordering of the light emitting layers. A QWI process makes use of the metastable nature of the compositional gradient found at heterointerfaces. The natural tendency for materials to interdiffuse is the basis for the intermixing process. Since the lower energy light emitting quantum well layers are surrounded by higher energy barriers of a different material composition, the interdiffusion of the well-barrier constituent atoms will result in higher energy light emitting layers and therefore a blue-shifted (or shorter) gain peak.

The rate at which this process takes place can be enhanced with the introduction of a catalyst. Using a lithographically definable catalyst patterning process, the QWI process can be made selective. This is the process by which virtually all selective QWI is performed, whether it is by the introduction of impurities or by the creation of vacancies. By using these techniques There are a great number of techniques that have evolved over the years to accomplish selective intermixing, such as impurity-induced disordering (IID), impurity-free vacancy-enhanced disordering (IFVD), photoabsorption-induced disordering (PAID), and implantation-enhanced interdiffusion to name just a few. Such methods are capable of shifting the peak gain wavelengths by 1 to over 100 nm. By employing one of these mentioned or any other QWI method to detune the gain peak of adjacent laser devices, the convolved lasing spectrum of the side by side devices can be altered.

In one embodiment, an laser apparatus capable of multiple wavelength is manufactured by using QWI processes described above. The apparatus includes a gallium and nitrogen containing substrate including a first crystalline surface region orientation. The apparatus also includes an active region comprising a barrier layer and a plurality of light emission layers, the plurality of light emission layers including a first emission layer and a second emission layer, the barrier layer being characterized by a first energy level, the first emission layer being characterized by a first wavelength and a second energy level, the second energy level being lower than the first energy level, the first emission layer having a first amount of material diffused from the barrier layer, the second emission layer being characterized by a second wavelength, a difference between the first gain peak wavelength and the second gain peak wave length being at least 10 nm. For example, the second emission layer has a second amount of material diffused from the barrier layer.

The apparatus also includes a first cavity member overlaying the first emission layer, the first cavity member being characterized by a length of at least 100 um and a width of at least 0.5 um, the first cavity member being adapted to emit a first laser beam at the first wavelength. The apparatus includes a second cavity member overlaying the second the emission layer, the second cavity member being characterized by a length of at least 100 um and a width of at least 0.5 um the second cavity member being adapted to emit a second laser beam at the second wavelength. The apparatus includes an output region wherein the first laser beam and the second laser beam are combined.

Depending on the application, the active region may includes various types of material, such as InP material, GaAs material, and others. the apparatus may have optics having dichroic coatings for combining the first and the second laser beam. In one embodiment, the apparatus includes a plurality of polarizing optics for combining the first and the second laser beam. In a specific embodiment, the first cavity member and the second cavity member share a common cleaved facet of mirror edges, which is configured to combine the first and second laser beams. The first and second laser beams can be associated with a number of color combinations. For example, the first wavelength is associated with a green color and the second wavelength is associated with a blue color.

It is to be appreciated that the laser apparatus can be implemented on various types of substrates. For example, the first crystalline surface region orientation can be a {20-21} or {20-2-1} plane, and first crystalline surface region orientation can also be a {30-31} or a {30-3-1} plane, or offcuts of these planes. The laser apparatus may also include other structures, such as a surface ridge architecture, a buried hetereostructure architecture, and/or a plurality of metal electrodes for selectively exciting the active region For example, the active region comprises a first and second gallium and nitrogen containing cladding layers and an indium and gallium containing emitting layer positioned between the first and second cladding layers. The laser apparatus may further includes an n-type gallium and nitrogen containing material and an n-type cladding material overlying the n-type gallium and nitrogen containing material.

In various embodiments, laser diodes formed on different substrates are packaged together. It is to be appreciated that by sharing packaging of laser diodes, it is possible to produce small device applications (e.g., pico projectors), as multiple laser diodes can tightly fit together. For example, light engines having laser diodes in multiple colors are typical capable of reducing the amount of speckles in display applications. In addition, co-packaged laser diodes are often cost-efficient, as typically fewer optics are needed to combined laser beam outputs from laser diodes as a result of sharing packages.

For example, copackaged lasers are used for some light engine in a display technology such as a pico projector and other applications. For example, the package could be an off the shelf laser diode package or some customed designed packaged which functions to house multiple laser diodes. In a preferred embodiment, a co-package laser devices is implemented using a green laser fabricated on {20-21} or {20-2-1} or a miscut of, a blue laser fabricated on {20-21} or a {20-2-1} or a miscut of, and a red laser diode fabricated from AlInGaP. In one embodiment, a co-package laser devices is implemented using a green laser fabricated on {20-21} or {20-2-1} or a miscut of, a blue laser fabricated on nonpolar m-plane or a miscut of, and a red laser diode fabricated from AlInGaP. In another embodiment, a co-package laser devices is implemented using a green laser fabricated on {20-21} or {20-2-1} or a miscut of, a blue laser fabricated on polar c-plane or a miscut of, and a red laser diode fabricated from AlInGaP. Merely as an example, for blue color emission, the relevant wavelengths cover 425 to 490 nm; for green color emission, wavelengths cover 490nm to 560 nm; for red color emission, the wavelengths cover 600 to 700 nm.

Depending on the application, various combinations of laser diode colors can be used. For example, following combinations of laser diodes are provided, but there could be others:
Blue polar+Green nonpolar+Red* AlInGaP
Blue polar+Green semipolar+Red* AlInGaP
Blue polar+Green polar+Red* AlInGaP
Blue semipolar+Green nonpolar+Red* AlInGaP
Blue semipolar+Green semipolar+Red* AlInGaP
Blue semipolar+Green polar+Red* AlInGaP
Blue nonpolar+Green nonpolar+Red* AlInGaP
Blue nonpolar+Green semipolar+Red* AlInGaP
Blue nonpolar+Green polar+Red* AlInGaP

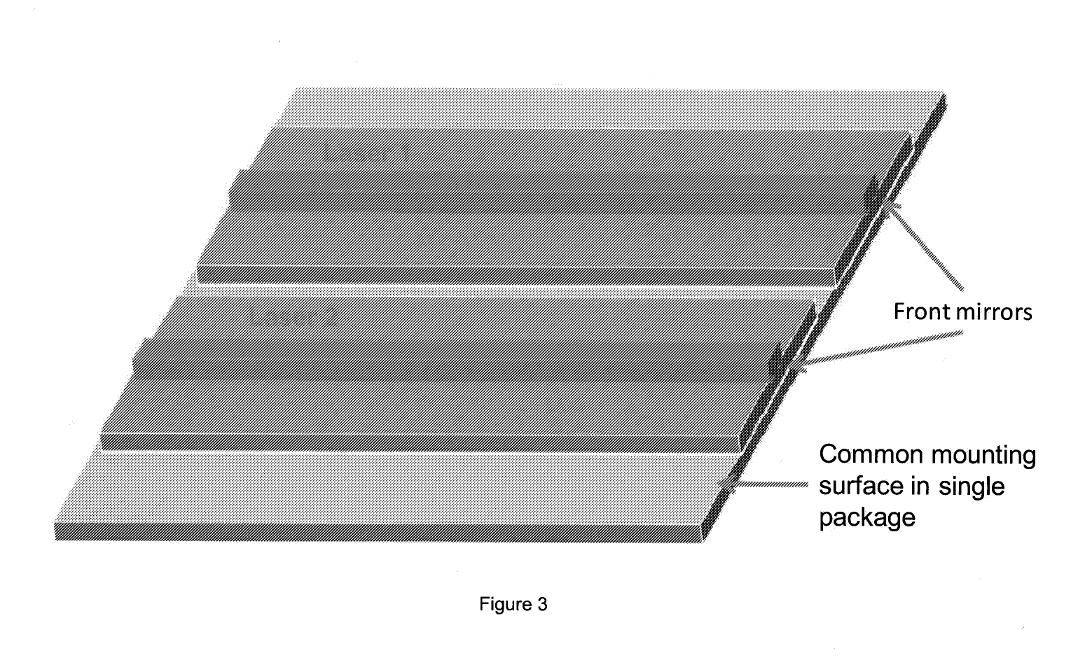

FIG. 3 is a diagram of copackaged green and blue laser diode mounted on common surface within a single package. For example, laser 1 could generate an output wavelength of blue (425-470 nm) or green (510-545 nm) and laser 2 could generate an output wavelength of blue or green. FIG. 3 only shows 2 lasers, but there could be a multitude of lasers on the single-chip. For example, the blue laser could be fabricated on nonpolar, semipolar, or polar GaN and the green laser could be fabricated on nonpolar or semipolar GaN.

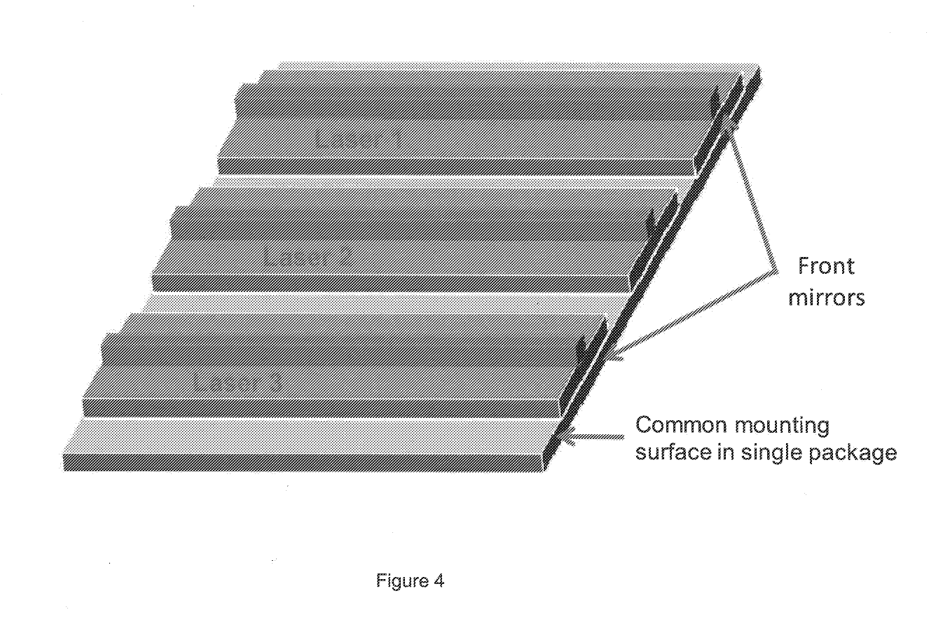

FIG. 4 is a simplified diagram of copackaged red, green, and blue laser diodes mounted on common surface within a single package. For example, laser 1 could generate an output wavelength of blue (425-470 nm) or green (510-545 nm) and laser 2 could generate an output wavelength of blue or green. FIG. 4 shows only 3 lasers, but there could be a multitude of lasers on the single-chip. The blue laser could be fabricated on nonpolar, semipolar, or polar GaN and the green laser could be fabricated on nonpolar or semipolar GaN.

According to on embodiment, an co-packaged laser device having multiple-colored laser diodes is provided. Device includes a back member having a first surface. For example, the back member is provided to mount multiple laser diodes.

The laser device includes a first laser diode. The first laser diode includes a first substrate mounted on the first surface of the back member, the first substrate comprising a gallium and nitrogen material, the first substrate having a first crystalline surface region orientation. The first laser diodes also includes a first active region comprising a first barrier layer and a first light emission layer, the first light emission layer being associated with a first wavelength. The first laser diode additionally includes a first cavity member overlaying the first light emission layer, the first cavity member being characterized by a length of at least 100 um and a width of at least 0.5 um, the first cavity member having a first surface, the first cavity member being adapted to emit a first laser beam at the first wavelength.

It is to be appreciated that according to package designs provided according to embodiments of the present invention, various types of laser diodes may be used. In one embodiment, the the first crystalline surface region orientation is polar. According to another embodiment, the first crystalline surface region orientation is nonpolar. In yet another embodiment, the first crystalline surface region orientation is semi-polar. For example, the first crystalline surface region orientation is semi-polar and the first wavelength is characterized by a green color.

The laser device also includes a second laser diode. The second laser diode includes a second substrate mounted on the first surface of the back member, the first substrate having a second crystalline surface region orientation. The second laser diode also includes a second active region comprising a second barrier layer and a second light emission layer, the second light emission layer being associated with a second wavelength, a difference between the first and second wavelengths being at least 10 nm. The second laser diode further includes a second cavity member overlaying a second light emission layer, the second cavity member being characterized by a length of at least 100 um and a width of at least 0.5 um, the second cavity member having a second surface, the first and second surfaces being substantially parallel, the second cavity member being adapted to emit a second laser beam at a second wavelength.

It is to be appreciated that the laser devices can have a number of laser diodes mounted on the back member. According to one embodiment, the laser device includes a third laser diode, which has a third substrate mounted on the first surface of the back member, the third substrate having a third crystalline surface region orientation. The third laser diode includes a third active region comprising a third barrier layer and a third light emission layer, the third light emission layer being associated with a third wavelength. The third laser diode also includes a third cavity member overlaying the third light emission layer, the third cavity member being characterized by a length of at least 100 m and a width of at least 0.5 um, the second cavity member having a third surface, the first and third surfaces being substantially parallel, the third cavity member being adapted to emit a third laser beam at a third wavelength.

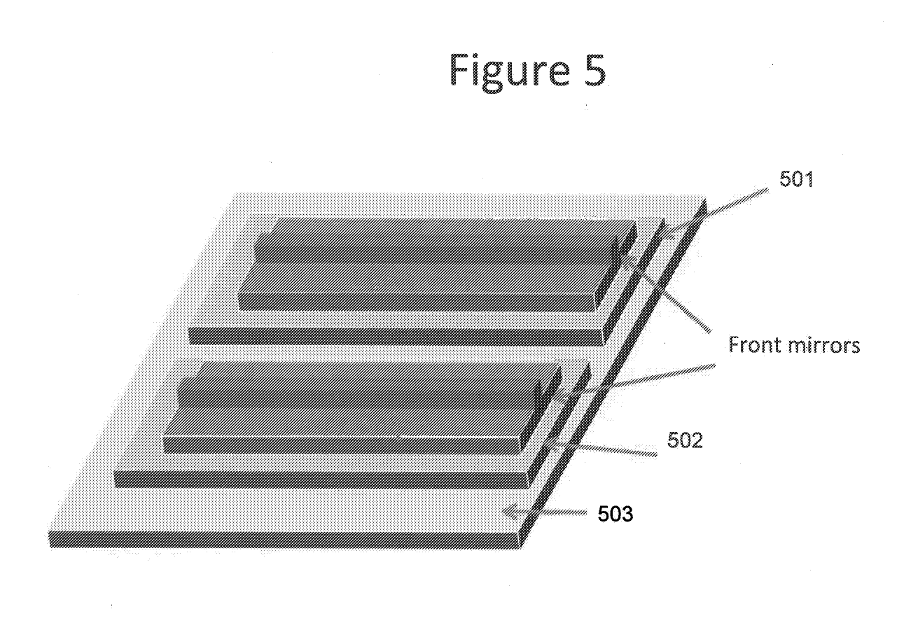

In various embodiments, laser chips that are mounted on separate submounts are packaged together on a shared submount. FIG. 5 is a simplified diagram illustrating two laser diodes sharing a submount according to an embodiment of the present invention. This diagram is merely an example, which should not unduly limit the scope of the claims. One of ordinary skill in the art would recognize many variations, alternatives, and modifications. As shown in FIG. 5, laser chip 1 and laser chip 2 are respectively mounted on their own submounts, and these two submounts are separated from each other. As shown, laser chip 1 is mounted on the submount 501; laser chip 2 is mounted on the submount 502. The two submounts 501 and 502 are mounted on a large submount 503. Depending on the application, the submount 501 can be a carrier submount or a package surface for the laser diodes. As an example, the laser 1 is configured to generate an output wavelength of blue (425-475 nm) or green (505-545 nm) and laser 2 could generate an output wavelength of blue or green. Other color combinations are possible as well, as described above. In addition, there are 2 lasers shown in FIG. 5, but there could be a multitude of lasers on the single-chip. The blue laser can be fabricated on nonpolar, semipolar, or polar GaN and the green laser could be fabricated on nonpolar or semipolar GaN. In a preferred embodiment, the front end of the laser chips face the same direction.

It is to be appreciated that the term “submount” and the term “back member” are used interchangeably. The back member or the submount may comprises various types of materials, such as AlN, BeO, diamond, copper, or other like materials. As an example, laser chips are placed on a submount that functions as carrier. For example, the submount 501 electrically conductive and can be used as a carrier that couples to a power source. The submount can be non-conductive as well. Depending on the application, laser diode can be attached to the submount by using solders such as AuSn on AlN, BeO, CuW, composite diamond, CVD diamond, copper, silicon, or other materials.

As an example, submounts 501 and 502 are attached to the submount 503 in various way, such as using soldering materials like AuSn, Indium, eutectic lead tin (36/64) and SAC (tin-silver-copper 94/4.5/0.5). The soldering material can be deposited on using various methods or processes. The submount 503 can be made of different types of materials, such as AlN, BeO, CuW, composite diamond, CVD diamond, copper, silicon, or other materials.

Laser diodes can be packaged in different ways for various purposes and/or applications. For example, many custom type packages can be used as we would expect RGB modules to have various new designs. Conventional form factors, such as TO header, C-mount, butterfly box, CS, micro-channel cooler, etc., can be incorporated into packaging

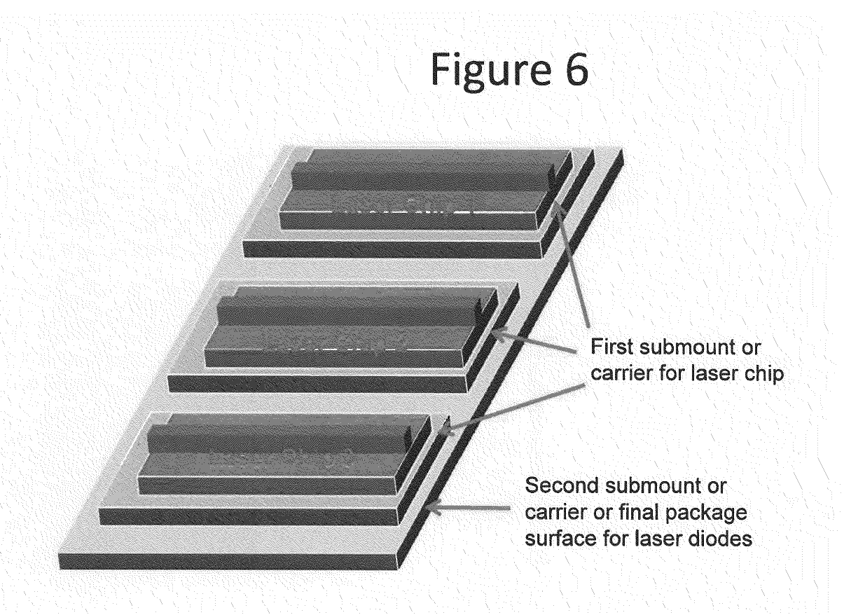

FIG. 6 is a diagram illustrating a co-packaged red, green, and blue laser device according to an embodiment of the present invention. This diagram is merely an example, which should not unduly limit the scope of the claims. One of ordinary skill in the art would recognize many variations, alternatives, and modifications. Red, green, and blue laser diodes are each mounted on their separate submounts or carriers, and these submounts or carriers are mounted on a second submount or carrier or on a common surface within a single package. Merely by way of an example, laser 1 could generate an output wavelength of blue (425-475 nm) or green (505-545 nm), and laser 2 could generate an output wavelength of blue or green. Laser 3 could be configured to generate an output red wavelength. It is to be appreciated that the co-packaged device may include additional laser diodes as well.

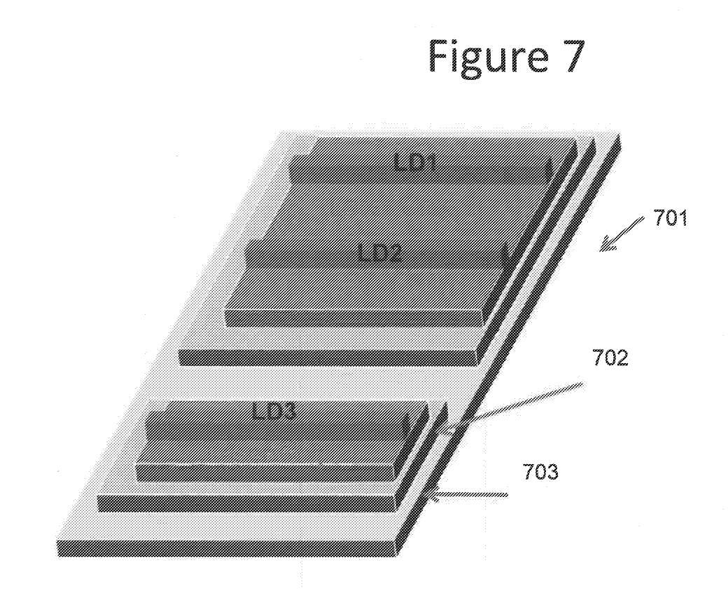

FIGS. 7-9 are diagrams illustrating laser diodes sharing one or more mounting structures. These diagrams are merely examples, which should not unduly limit the scope of the claims. One of ordinary skill in the art would recognize many variations, alternatives, and modifications. As shown in FIG. 7 red, green, and blue laser diodes are packaged together. More specifically, laser diodes 1 and 2 are monolithically integrated onto the laser chip 1 and are mounted on submount 701. The laser diode 3 is on laser chip 2 and mounted on submount 702. The submounts 701 and 702 are mounted on submount 703, which can be a carrier or on a common surface within a single package. The laser diode 1 could generate an output wavelength of blue (425-475 nm) or green (505-545 nm) and laser 2 could generate an output wavelength of blue or green. As an example, the blue and green lasers could be fabricated on nonpolar or semipolar GaN. It is to be appreciated that other combinations are possible as well. For example, laser diode 1 and laser diode 2 can both be green or blue, or other colors.

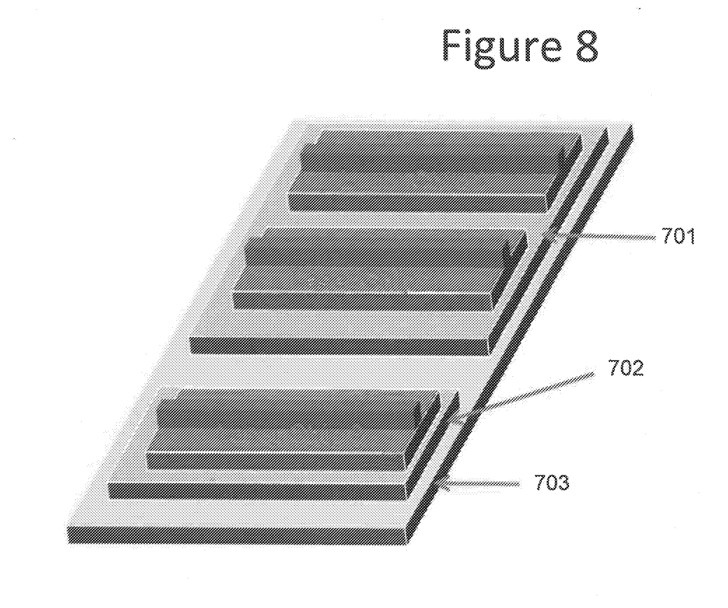

FIG. 8 provides an example of copackaged red, green, and blue laser diode. The laser chips 1 and 2 share a submount 701. The laser chip 3 is on submount 702 that is separate from submount 701. Then submounts 701 and 702 are mounted on submount 703, which can be a carrier or on a common surface within a single package. As an example, laser 1 could generate an output wavelength of blue (425-475 nm) or green (505-545 nm) and laser 2 could generate an output wavelength of blue or green. Other color combinations are possible as well. FIG. 8 shows only 2 laser diodes on the submount 701, but there could be a number of laser diodes on the single-chip. The blue laser could be fabricated on nonpolar, semipolar, or polar GaN and the green laser could be fabricated on nonpolar or semipolar GaN.

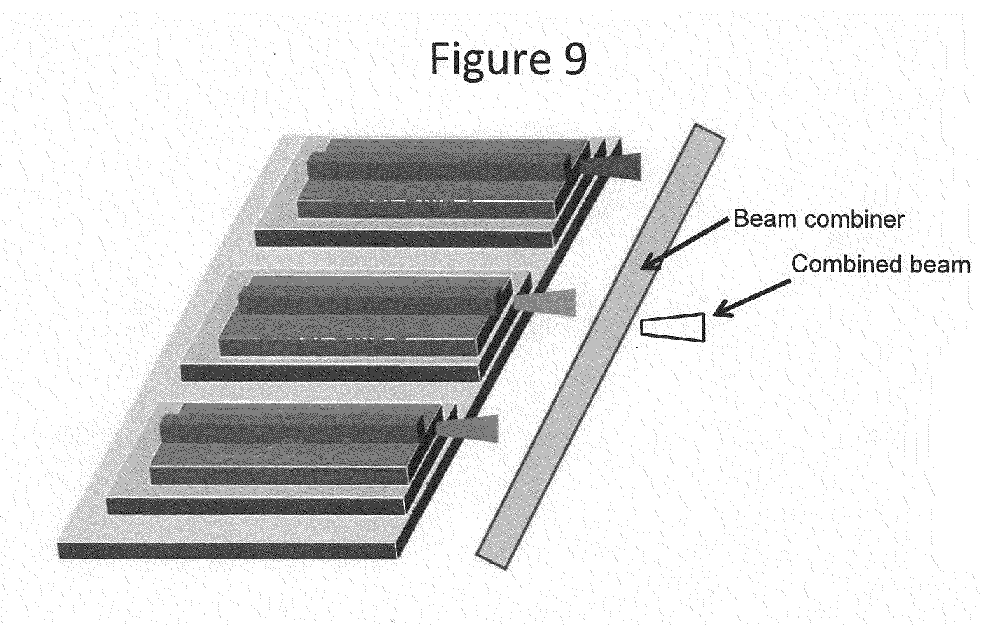

FIG. 9 provides an example of copackaged red, green, and blue laser diode. As shown in FIG. 9, optical output beams are collimated into a common beam using a beam combiner member or configuration. This is merely and example and the laser could be arranged in many possible configurations and the beam combiner could be comprised of components such as dichroic mirrors, ball lens, or some combination of these plus others.

The laser device may include one or more optical members for combining laser beams. In one embodiment, the laser devices includes a plurality of polarizing optics for combining the first and the second laser beams. In another embodiment, an optical member for combining the first and second laser beams at an output region.

As explained above, various combinations of laser diodes are provided according to embodiments of the present invention, which is listed as the following:
1. the first crystalline surface region orientation is semi-polar;the second crystalline surface region orientation is non-polar;
2. the first crystalline surface region orientation is semi-polar;the second crystalline surface region orientation is polar.
3. the first crystalline surface region orientation is polar; the second crystalline surface region orientation is non-polar.
4. the first light emitting layer comprises AlInGaP material;the first wavelength is characterized by a red color.
5. the first light emitting layer comprises AlInGaP material; the first wavelength is characterized by a red color; the second crystalline surface region orientation is non-polar; the second wavelength is characterized by a green color.
6. the first light emitting layer comprises AlInGaP material; the first wavelength is characterized by a red color; the second crystalline surface region orientation is non-polar; the second wavelength is characterized by a blue color.
7. the first light emitting layer comprises AlInGaP material; the first wavelength is characterized by a red color; the second crystalline surface region orientation is semi-polar; the second wavelength is characterized by a blue color.
8. the first light emitting layer comprises AlInGaP material;the first wavelength is characterized by a red color; the second crystalline surface region orientation is semi-polar; the second wavelength is characterized by a green color.

The co-packaged laser device may include additional structures, which can be parts of the laser diodes. For example, one more laser diodes may includes a surface ridge architecture a buried hetero-structure architecture, and/or a plurality of metal electrodes for selectively exciting the active regions.

While the above is a full description of the specific embodiments, various modifications, alternative constructions and equivalents may be used. Therefore, the above description and illustrations should not be taken as limiting the scope of the present invention which is defined by the appended claims.

What is claimed is:

1. An optical device comprising:
a gallium and nitrogen containing substrate including a first crystalline surface region of semi-polar or non-polar orientation;
an active region comprising a barrier layer and a light emission layer, the light emission layer being characterized by a graduated profile associated with a peak emission wavelength gradient, the peak emission wavelength gradient having a deviation of at least 10 nm;
a first cavity member overlaying a first portion of the emission layer, the first portion of the emission layer being associated with a first wavelength, the first cavity member being characterized by a length of at least 100 um and a width of at least 0.5 um, the first cavity member being adapted to emit a first laser beam at the first wavelength;
a second cavity member overlaying a second portion of the emission layer, the second portion of the emission layer being associated with a second wavelength, a difference between the first and second wavelengths being at least 50 nm, the second cavity member being characterized by a length of at least 100 um and a width of at least 0.5 um, the second cavity member being adapted to emit a second laser beam at a second wavelength; and
an output region.

2. The device of claim 1 wherein:
the first wavelength is associated with a green color;
the second wavelength is associated with a blue color.

3. The device of claim 1 further comprising a plurality of metal electrodes for selectively exciting the active region.

4. The device of claim 1 wherein the active region comprises at least four quantum well regions.

5. The device of claim 1 wherein the active region is configured operably for a forward voltage of <7V for an output power of 60 mW and greater.

6. An optical device comprising:
a back member having a first surface;
a first substrate mounted on the first surface of the back member, the first substrate comprising a gallium and nitrogen material, the first substrate having a first crystalline surface region orientation, the first crystalline surface orientation being semi-polar or non-polar;
a first active region comprising a first barrier layer and a first light emission layer, the first light emission layer being associated with a first wavelength;
a second substrate mounted on the first surface of the back member, the first substrate having a second crystalline surface region orientation;
a second active region comprising a second barrier layer and a second light emission layer, the second light emission layer being associated with a second wavelength, a difference between the first and second wavelengths being at least 10 nm;
a first cavity member overlaying the first light emission layer, the first cavity member being characterized by a length of at least 100 um and a width of at least 0.5 um, the first cavity member having a first surface, the first cavity member being adapted to emit a first laser beam at the first wavelength;
a second cavity member overlaying a second light emission layer, the second cavity member being characterized by a length of at least 100 um and a width of at least 0.5 um, the second cavity member having a second surface, the first and second surfaces being substantially parallel, the second cavity member being adapted to emit a second laser beam at a second wavelength; and
an output region.

7. The device of claim 6 wherein the first wavelength is about 420 nm to 490 nm and the second wavelength is about 490 nm to 560 nm.

8. The device of claim 6 further comprising:
a third substrate mounted on the first surface of the back member, the third substrate having a third crystalline surface region orientation;
a third active region comprising a third barrier layer and a third light emission layer, the third light emission layer being associated with a third wavelength;
a third cavity member overlaying the third light emission layer, the third cavity member being characterized by a length of at least 100 um and a width of at least 0.5 um, the second cavity member having a third surface, the first and third surfaces being substantially parallel, the third cavity member being adapted to emit a third laser beam at a third wavelength.

9. The device of claim 6 wherein the first crystalline surface region orientation is polar, non-polar, or semi-polar.

10. The device of claim 6 wherein the first crystalline surface region orientation is semi-polar and the first wavelength is characterized by a green color.

11. The device of claim 6 wherein the first crystalline surface region orientation is on the c-plane and the first wavelength is characterized by a blue color.

12. The device of claim 6 wherein:
the first light emitting layer comprises AlInGaP material;
the first wavelength is characterized by a red color;
the second crystalline surface region orientation is semi-polar;
the second wavelength is characterized by a green color.

13. The device of claim 6 further comprising a plurality of optics having dichroic coatings for combining the first and the second laser beams.

14. The device of claim 6 further comprising a plurality of polarizing optics for combining the first and the second laser beams.

15. The device of claim 6 further comprising an optical member for combining the first and second laser beams at the output region.

16. The device of claim 6 wherein first crystalline surface region orientation is a {20-21} plane or {30-31} plane.

17. An optical device comprising:
a first submount;
a second submount having a first top surface and a first bottom surface, the first bottom surface being coupled to the first submount;
a third submount having a second top surface and a second bottom surface, the second bottom surface being coupled to the first submount, the third submount being separated from the second submount;
a first substrate mounted on the first top surface, the first substrate comprising a gallium and nitrogen material, the first substrate having a first crystalline surface region orientation, the first crystalline surface orientation being semi-polar or non-polar, the first substrate comprising a first barrier layer and a first light emission layer, the first light emission layer being associated with a first wavelength;
a first cavity member overlaying the first light emission layer, the first cavity member being characterized by a length of at least 100 um and a width of at least 0.5 um, the first cavity member having a first surface, the first cavity member being adapted to emit a first laser beam at the first wavelength;
a second substrate mounted on the second top surface;
a second cavity member overlaying the second substrate, the second cavity member being associated with a second wavelength.

18. The device of claim 17 wherein the first substrate second substrate is characterized by a polar orientation.

19. The device of claim 17 further comprising a third cavity member overlaying the first substrate, the third cavity member being associated with a third wavelength different from the first wavelength.

20. The device of claim 17 further comprising a third substrate mounted on the first top surface, the third substrate being separated from the first substrate, the third substrate being associated with a semipolar or non-polar orientation.

21. The device of claim 17 further comprising:
a third submount, the third substrate being separate from the first submount and the second submount;
a third substrate mounted on the third submount;
a third cavity member overlaying the third substrate.
